(19) United States
(12) Patent Application Publication
(10) Pub. No.: US 2011/0146752 A1
(43) Pub. Date: Jun. 23, 2011

(54) Solar module and solar array

(76) Inventor: Jongho Park, Suwon-si (KR)

(21) Appl. No.: 12/805,668

(22) Filed: Aug. 12, 2010

(30) Foreign Application Priority Data
Dec. 22, 2009 (KR) 10-2009-0128874

(51) Int. Cl. H01L 31/052

(52) U.S. Cl. 136/246

(57) ABSTRACT

A solar module includes a plurality of plate-shaped solar cells adjacent to each other, each solar cell having a polygonal cross-section from a plan view and at least one outer surface facing away from an interior of the solar module, and a fluid circulation tube along the outer surfaces of the solar cells, the fluid circulation tube including cooling fluid.

### BACKGROUND

1. Field

Embodiments relate to a solar module and a solar array.

2. Description of the Related Art

Solar photovoltaics (PVs) collect sunlight into solar cells or a solar array to generate electricity. A solar module includes a plurality of solar cells, and a solar array includes a plurality of solar modules. Specifically, each of the solar cells includes an N-type semiconductor and a P-type semiconductor. When sunlight is irradiated into the solar cells, electricity is generated due to a photovoltaic effect in which current flows by solar energies.

### SUMMARY

Embodiments are directed to a solar module and a solar array, which substantially overcome one or more of the problems due to the limitations and disadvantages of the related art.

It is therefore a feature of an embodiment to provide a solar module and a solar array, which continuously maintain performance of a solar cell to improve photovoltaic power generation efficiency.

At least one of the above and other features and advantages may be realized by providing a solar module, including a plurality of plate-shaped solar cells adjacent to each other, each solar cell having a polygonal cross-section from a plan view and at least one outer surface facing away from an interior of the solar module, and a fluid circulation tube along the outer surfaces of the solar cells, the fluid circulation tube including cooling fluid.

The plurality of solar cells may be arranged adjacent to each other to form a square shape or a hexagonal shape. The fluid circulation tube may contact and overlap an entire outer surface of each solar cell.

The solar module may further include a solar cell support part at a first lower portion of a respective solar cell, the solar cell support part being configured to support the solar cell, and the first lower portion of the solar cell being at an edge of the solar cell adjacent to the fluid circulation tube, and a solar cell support motion part at a second lower portion of the solar cell, the second lower portion being at an opposite edge of the solar cell with respect to the first lower portion, and the solar cell support motion part being configured to support and move the opposite edge of the solar cell.

The solar cell support motion part may be controlled by a photovoltaic sensor detecting a portion of the sun with respect to the solar module and a first controller determining an angle of the respective solar cells through the position information of the sun detected by the photovoltaic sensor.

The solar cell support motion part may include a solar cell rack gear disposed at the second lower portion of the solar cell, a solar cell pinion gear disposed to correspond to the solar cell rack gear, the solar cell pinion gear being configured to vertically move the solar cell rack gear in order to move the opposite edge of the solar cell, and a first controller configured to control the solar cell pinion gear.

The solar module may further include a cleaning part at least partially within the fluid circulation tube, the cleaning part being configured to eject a portion of the cooling fluid from the fluid circulation tube onto top surfaces of the solar cells.

The cleaning part may include a water tube connected to a water tank, a pump configured to pump fluid from the water tank to the water tube, a valve configured to regulate an amount of water passing through the pump, a water support connected between the water tube and the fluid circulation tube, the water support being configured to support the fluid circulation tube, a nozzle within the fluid circulation tube, the nozzle being configured to eject the cooling fluid from the fluid circulation tube onto the top surfaces of the solar cells, and a second controller configured to control the pump and the valve.

A top surface of the nozzle may be parallel to that of the fluid circulation tube when a photovoltaic power is generated and higher than that of the fluid circulation tube when the cleaning process is performed.

The cleaning part may include a cleaning rack gear disposed at a lower portion of the nozzle, and a cleaning pinion gear disposed corresponding to the cleaning rack gear, the cleaning pinion gear being coupled to a driving motor to vertically move the nozzle, wherein the driving motor may be controlled by a second controller.

The solar module may further include a water discharge part through which the water used for cleaning the top surface of the respective solar cells is discharged, the water discharge part being disposed below and spaced from the plurality of solar cells.

The water discharge part may include a water discharge funnel disposed below the plurality of solar cells, the water discharge funnel collecting the water used for cleaning the top surface of the respective solar cells, a water discharge tube extending from the water discharge funnel, and a water discharge tank connected to the water discharge tube, the water discharge tank storing the water used for cleaning the top surface of the respective solar cells.

At least one of the above and other features and advantages may also be realized by providing a solar array, including a plurality of solar cell assemblies disposed spaced from each other, the plurality of solar cell assemblies including a plurality of plate-shaped solar cells in which at least one outer surface thereof is exposed to the outside, the solar cells, each having a polygonal shape, being disposed adjacent to each other, and a fluid circulation tube in which water is circulated therein, the fluid circulation tube being disposed along the outer surface of the respective solar cells exposed to the outside, wherein each of the solar cell assemblies has a polygonal shape. Each of the solar cell assemblies may have a square or hexagonal shape.

The solar array may further include a solar cell support part disposed at one side lower portion of the solar cell adjacent to the fluid circulation tube, the solar cell support part supporting the solar cells, a solar cell support motion part disposed at the other side lower portion of the solar cell, the solar cell support motion part supporting and vertically moving the solar cells, and a first controller controlling the solar cell support motion part.

The solar array may further include a photovoltaic sensor detecting a portion of the sun with respect to the solar array, wherein the first controller may determine an angle of the respective solar cells through the position information of the sun detected by the photovoltaic sensor to control the solar cell support motion part.

The solar array may further include a water support connected to the fluid circulation tube, the water support supporting the fluid circulation tube, a water tube connected to the water support, and a water tank connected to the water tube.

The solar array may further include a cleaning part cleaning a top surface of the respective solar cells using the water within the fluid circulation tube.

The cleaning part may include a pump pumping out the water stored in the water tank, a valve regulating an amount of the water passing through the pump, a nozzle injecting the water passing through the valve onto the top surface of the respective solar cells, and a second controller controlling the pump and the valve.

The cleaning part may include a cleaning rack gear disposed at a lower portion of the nozzle, and a cleaning pinion gear disposed corresponding to the cleaning rack gear, the cleaning pinion gear being coupled to a driving motor to vertically move the nozzle, wherein the driving motor is controlled by the second controller.

The solar array may further include a water discharge part through which the water used for cleaning the top surface of the respective solar cells is discharged, the water discharge part being disposed below and spaced from the plurality of solar cell assemblies.

The water discharge part may include a water discharge funnel disposed below the plurality of solar cell assemblies, the water discharge funnel collecting the water used for cleaning the top surface of the respective solar cells, a water discharge tube extending from the water discharge funnel, and a water discharge tank connected to the water discharge tube, the water discharge tank storing the water used for cleaning the top surface of the respective solar cells.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1A illustrates a plan view of a solar module according to an embodiment;

FIG. 1B illustrates a plan view of a solar array according to an embodiment;

FIG. 2A illustrates a plan view of a solar module according to another embodiment;

FIG. 2B illustrates a plan view of a solar array according to another embodiment;

FIG. 3A illustrates a detailed schematic view of a solar module according to an embodiment;

FIG. 3B illustrates a schematic view of movement of solar cells with respect to a position of the sun in a solar module according to an embodiment; and

FIG. 3C illustrates a schematic view of a cleaning process of a solar module according to an embodiment.

### DETAILED DESCRIPTION

Korean Patent Application No. 10-2009-0128874, filed on Dec. 22, 2009, in the Korean Intellectual Property Office, and entitled: “Solar Module and Solar Array,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of elements and regions may be exaggerated for clarity of illustration. It will also be understood that when a layer or element is referred to as being “on” another element or substrate, it can be directly on the other element or substrate, or intervening elements may also be present. In addition, it will also be understood that when an element is referred to as being “between” two elements, it can be the only element between the two elements, or one or more intervening elements may also be present. Like reference numerals refer to like elements throughout.

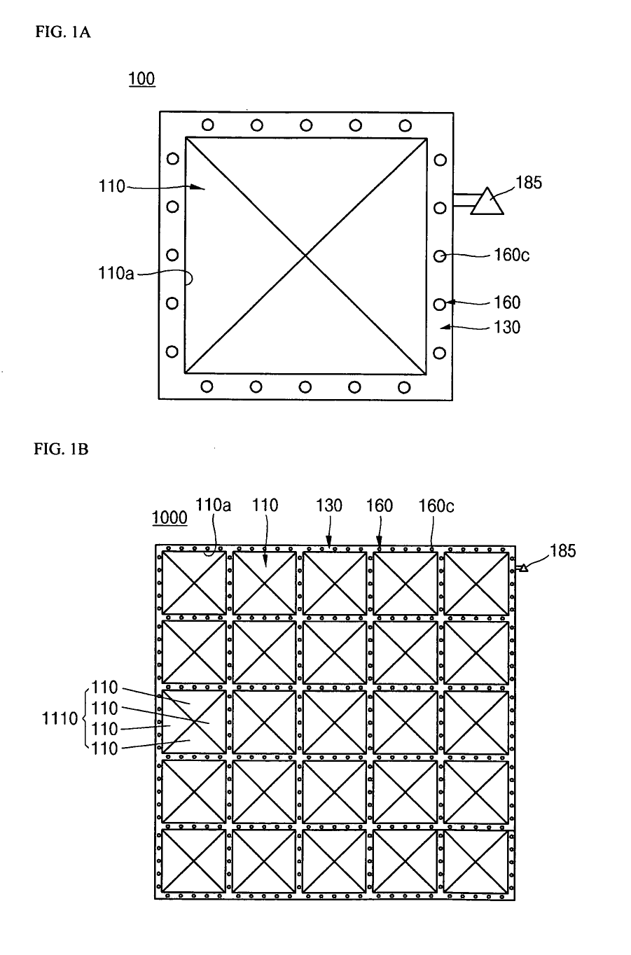

Hereinafter, a configuration of a solar module according to an embodiment will be described with reference to FIG. 1A. FIG. 1A illustrates a plan view of a solar module according to an embodiment.

Referring to FIG. 1A, a solar module 100 according to an embodiment may include a plurality of solar cells 110 and a fluid circulation tube 130. The solar module may further include a cleaning part 160 and a photovoltaic sensor 185.

Each of the solar cells 110 may have a plate shape, e.g., a shape of a sheet having a substantially flat structure with. The plurality of solar cells 110 may be arranged adjacent to each other. At least one outer surface 110a of the solar cell 110 may not be adjacent to the other solar cells 110, and may be exposed to the outside. As illustrated in FIG. 1A, the solar cell 110 may have a polygonal cross-section as viewed from a plan view, e.g., a triangular shape. The plurality of solar cells 110 may be arranged adjacent to each other to form a predetermined shape, e.g., a square shape, on the whole. For example, as illustrated in FIG. 1A, a plurality of triangularly shaped solar cells 110 may be arranged into a square shape, e.g., each triangularly shaped solar cell 110 may have two sides adjacent to two different solar cells 110 and one side, i.e., the outer surface 110a, exposed to the outside and defining one side of the square shape. The solar cells 110 generate electricity using a photovoltaic effect of sunlight.

The fluid circulation tube 130 may be disposed along the outer surface 110a of the solar cell 110 that is exposed to the outside, i.e., the outer surface 110a may face away from an interior of the solar module 100. For example, as illustrated in FIG. 1A, if four solar cells 110 are arranged in a square shape, the fluid circulation tube 130 may be disposed along the four sides of the square shape, i.e., along the four outer surfaces 110a of the four solar cells 110, to have a square shape. Cooling fluid, e.g., water, may be circulated inside the fluid circulation tube 130. The fluid circulation tube 130 may be formed of a metal having high thermal conductivity, e.g., one or more of copper, aluminum, or its equivalent, but is not limited thereto. The fluid circulation tube 130 may contact, e.g., directly contact, the solar cells 110, which directly receive the sunlight and are heated by the sunlight. Thus, the cooling fluid flowing in the fluid circulation tube 130 formed of a metal having high thermal conductivity may cool the heated solar cells 110. It is noted that hereinafter “water” will be used interchangeable with a “cooling fluid” for convenience. However, “water” is only an example of a cooling fluid and any other suitable cooling fluid may be used in the fluid circulation tube 130.

The cleaning part 160 may include a nozzle 160c. The water may be injected from the fluid circulation tube 130 onto a top surface of the solar cell 110, i.e., a surface facing the sun, through the nozzle 160c to remove pollutants, e.g., fugitive dusts, from the top surface of the solar cell 110. Thus, since a cleaning process is performed on the top surface of the solar cell 110, optical transmittance of the solar cell 110 may be improved, and power generation efficiency of the solar cell 110 may be highly maintained.

The photovoltaic sensor 185 may be disposed at a side of the fluid circulation tube 130. The photovoltaic sensor 185 may detect a position of the sun with respect to the solar cell 110.

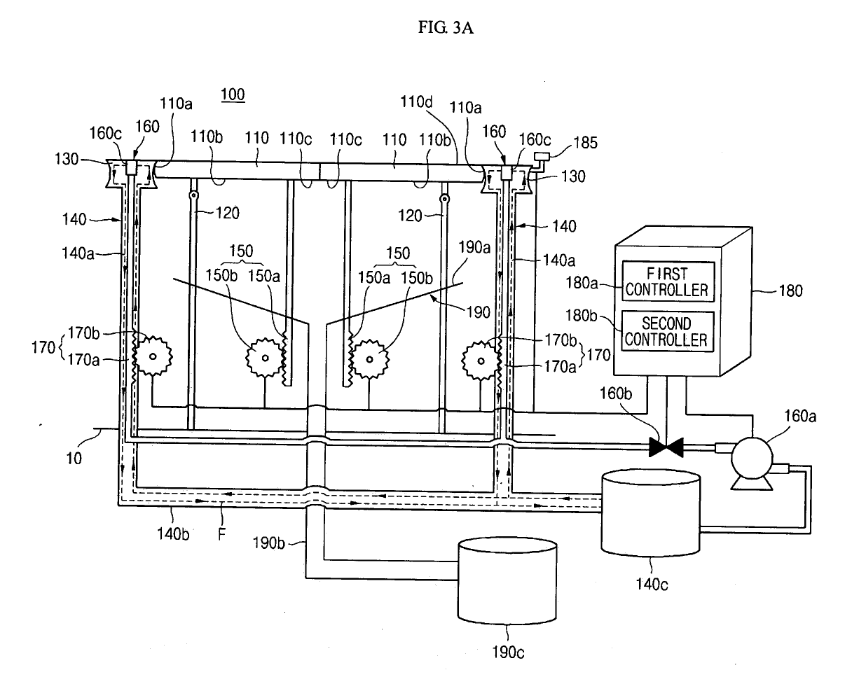

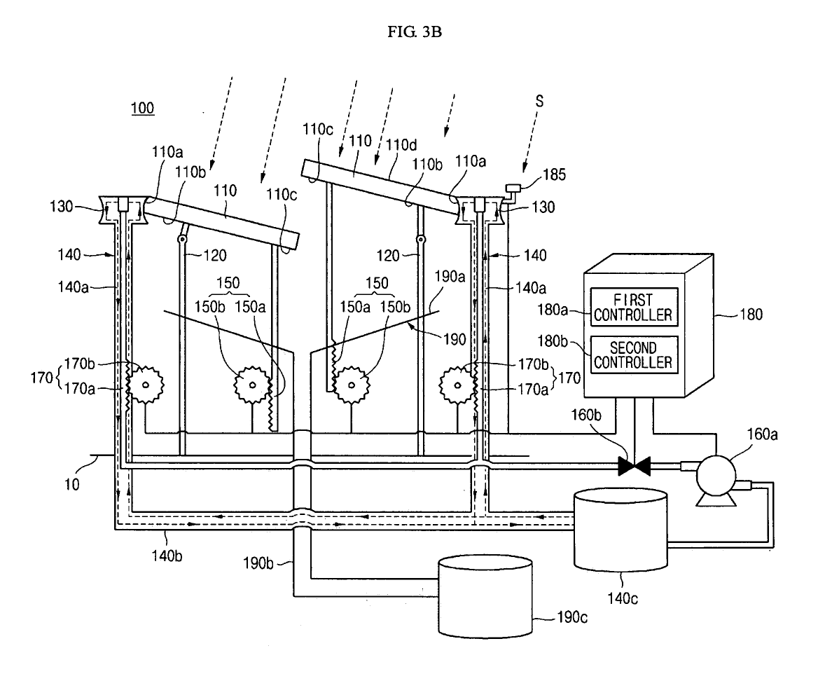

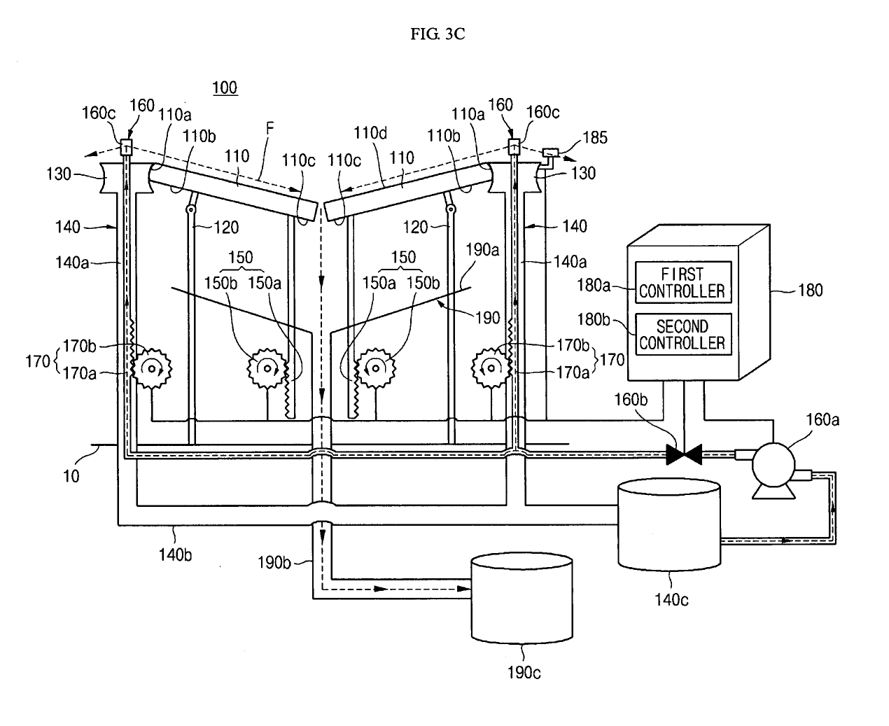

A description of the fluid circulation tube 130, the cleaning part 160, and the photovoltaic sensor 185 will be provided in more detail below with reference to FIGS. 3A-3C. Hereinafter, a configuration of a solar array according to an embodiment will be described with reference to FIG. 1B.

FIG. 1B illustrates a plan view of a solar array according to an embodiment. Referring to FIG. 1B, a solar array 1000 according to an embodiment may have an array form including a plurality of the solar modules 100, e.g., a plurality of the solar modules 100 arranged in a matrix pattern, so a number of arrays of solar cells 110 in the solar array 1000 may be different from a number of solar cells 110 in the solar module 100. In descriptions of the solar array 1000 according to an embodiment, the different points will now be mainly described. Also, the same constituents as in FIG. 1A will have the same name and reference numeral as in FIG. 1A, and the explanation thereof will be omitted.

The solar array 1000 may include a plurality of solar cell assemblies 1110 and the fluid circulation tube 130. The solar array 1000 may further include the cleaning part 160 and the photovoltaic sensor 185.

The solar cell assemblies 1110 may be arranged adjacent to each other, and may be equivalent to the solar modules 100 described previously with reference to FIG. 1A. The solar cell assemblies 1110 may include a plurality of solar cells 110 in which at least one outer surface 110a is exposed to the outside. Also, the plurality of solar cell assemblies 1110 may be arranged to be spaced apart from each other. Each of the solar cell assemblies 1110 may have a polygonal shape. Also, each of the solar cells 110 may have a triangular shape. Each of the solar cell assemblies 1110 may have a square shape. When the solar cell assembly 1110 has a square shape, generation efficiency of the solar array 1000 may be improved because the solar cell assemblies 1110 may be effectively arranged.

The fluid circulation tube 130 may be disposed along the outer surface 110a of the solar cell 110. Also, water may be circulated inside the fluid circulation tube 130.

The cleaning part 160 may include the nozzle 160c. The water may be injected onto the top surface of the solar cell 110 through the nozzle 160c. The photovoltaic sensor 185 may be disposed at a side of the fluid circulation tube 130.

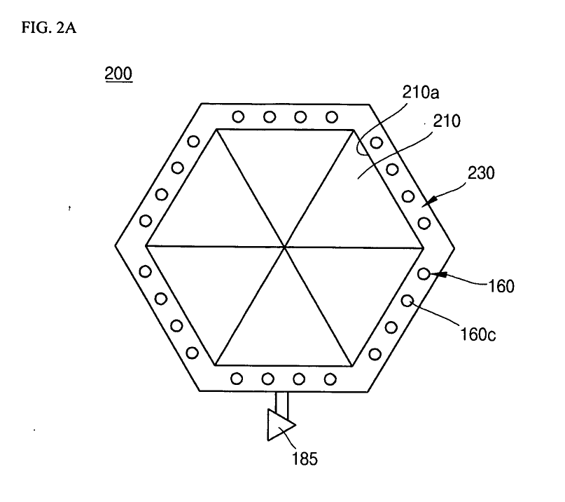

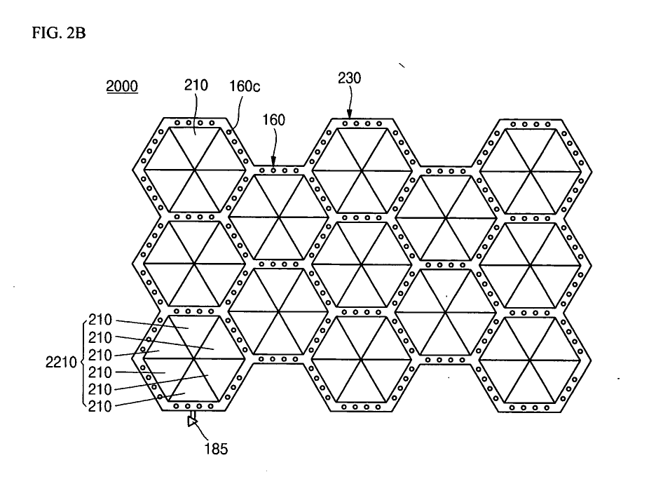

Hereinafter, a configuration of a solar module according to another embodiment will be described with reference to FIG. 2A. FIG. 2A illustrates a plan view of a solar module according to another embodiment.

Referring to FIG. 2A, a solar module 200 according to another embodiment may include structures of a solar cell 210 and a fluid circulation tube 230 different from those of the solar module 100 of FIG. 1A. Thus, in descriptions of the solar module 200 according to another embodiment, the solar cell 210 and the fluid circulation tube 230 will now be mainly described. Also, the same constituents as those of the solar module of FIG. 1A will have the same name and reference numeral as in FIG. 1A, and the explanation thereof will be omitted.

The solar cell 210 may have a plate shape. The plurality of solar cells 210 may be arranged adjacent to each other. At least one outer surface 210a of the solar cell 210 may not be adjacent to the other solar cell 210 and may be exposed to the outside. The solar cell 210 may have a polygonal shape, e.g., a triangular shape, and the plurality of solar cells 210 may be arranged adjacent to each other to form a hexagonal shape on the whole. The solar cells 210 generate electricity using a photovoltaic effect of sunlight.

The fluid circulation tube 230 may be disposed along the outer surface 210a of the solar cell 210 exposed to the outside. Water may be circulated inside the fluid circulation tube 230. The fluid circulation tube 230 may be formed of one or more of copper, aluminum, or its equivalent, which are high thermal conductivity metals, but is not limited thereto. The fluid circulation tube 230 may contact the solar cells 210 that directly receive sunlight and are heated by the sunlight. Thus, the water flowing along the fluid circulation tube 230 formed of a metal having the high thermal conductivity may cool heat of the solar cells 210.

Hereinafter, a configuration of a solar array according to another embodiment will be described with reference to FIG. 2B. FIG. 2B illustrates a plan view of a solar array according to another embodiment.

Referring to FIG. 2B, a solar array 2000 according to another embodiment may have an array form and a number of arrays of solar cells 210 different from those of the solar cells 210 of the solar module 200 of FIG. 2A. In descriptions of the solar array 2000 according to another embodiment, the different points will now be mainly described. Also, the same constituents as in FIG. 2A will have the same name and reference numeral as in FIG. 2A, and the explanation thereof will be omitted.

The solar array 2000 may include a plurality of solar cell assemblies 2210 and the fluid circulation tube 230. The solar array 2000 may further include the cleaning part 160 and the photovoltaic sensor 185.

The solar cell assemblies 2210 may be arranged adjacent to each other. The solar cell assemblies 2210 may include a plurality of solar cells 210 in which at least one outer surface 210a is exposed to the outside. Also, the plurality of solar cell assemblies 2210 may be arranged to be spaced apart from each other. Each of the solar cell assemblies 2210 may have a polygonal shape. Also, each of the solar cells 210 may have a triangular shape. Each of the solar cell assemblies 2210 may have a hexagonal shape. When the solar cell assembly 2210 has the hexagonal shape, generation efficiency of the solar array 2000 may be improved because the solar cell assemblies 2210 can be effectively arranged.

The fluid circulation tube 230 may be disposed along the outer surface 210a of the solar cell 210. Also, water may be circulated inside the fluid circulation tube 230.

The cleaning part 160 may include the nozzle 160c. The water may be injected onto the top surface of the solar cell 210 through the nozzle 160c.

The photovoltaic sensor 185 may be disposed at a side of the fluid circulation tube 230. The photovoltaic sensor 185 may detect a position of the sun with respect to the solar module 200.

Hereinafter, a detailed configuration and operation of a solar module and a solar array according to an embodiment will be described with reference to FIGS. 1A, 1B, and 3A. FIG. 3A illustrates a schematic view when a photovoltaic power is generated in the solar module according to an embodiment.

Referring to FIGS. 1A, 1B, and 3A, the solar module 100 according to an embodiment may include the plurality of solar cells 110 and the fluid circulation tube 130. As illustrated in FIG. 3A, the solar module 100 may further include a solar cell support part 120, a water part 140, a solar cell support motion part 150, the cleaning part 160, a cleaning part support motion part 170, a control part 180, the photovoltaic sensor 185, and a water discharge part 190.

As illustrated in FIG. 3A, each of the solar cells 110 may have a plate shape, and may have first and second lower portions 110b and 110c. The first lower portion 110b may be adjacent the outer surface 110a and the fluid circulation tube 130, and the second lower portion 110c may face a same direction as the first lower portion 110b and may be adjacent a neighboring solar cell 110, e.g., second lower portions 110c of neighboring solar cells 110 may be adjacent to each other. The plurality of solar cells 110 may be arranged adjacent to each other. At least one outer surface 110a of the solar cell 110 may not be adjacent to the other solar cell 110 and may be exposed to the outside. The solar cell 110 may have a polygonal shape. The plurality of solar cells 110 may be arranged adjacent to each other to form the solar cell assemblies 1110. The plurality of solar cell assemblies 1110 may be arranged spaced apart from each other to form the solar array 1000.

The solar cell support part 120 may be disposed at one side of the solar cell 110, e.g., the lower portion 110b of the solar cell 110 may be adjacent to and positioned on the solar cell support part 120. The solar cell support part 120 may be disposed on a reference surface 10 by which the solar cell module 100 is supported. The solar cell support part 120 may support the solar cell 110 during the photovoltaic power generation of the solar cell 110 and the cleaning process.

The fluid circulation tube 130 may be disposed along the outer surface 110a of the solar cell 110 exposed to the outside. For example, the fluid circulation tube 130 may overlap the entire outer surface 110a. The fluid circulation tube 130 may be formed of copper, aluminum, or its equivalent, which are high thermal conductivity metals, but is not limited thereto. The fluid circulation tube 130 may contact the solar cells 110 that directly receive the sunlight and are heated by the sunlight. Thus, the water flowing along the fluid circulation tube 130 formed of the metal having the high thermal conductivity may cool the heat of the solar cells 110.

The water part 140 may include a water support 140a, a water tube 140b, and a water tank 140c. The water support 140a may be connected to the fluid circulation tube 130. Also, a space may be defined in the water support 140a. The other end opposite to one end of the water support 140a connected to the fluid circulation tube 130 may be disposed on the reference surface 10 by which the solar cell module 100 is supported. For example, the water support 140a may extend along a vertical direction from the fluid circulation tube 130 to the reference surface 10. The water tube 140b may be connected to the water support 140a, and may include a space defined therein. The water tank 140c may be connected to the water tube 140b, so the water may be circulated between the fluid circulation tube 130 and the water tank 140c through the water support 140a and the water tube 140b. Thus, warm water having a temperature increased by the sunlight in the fluid circulation tube 130 may be stored in the water tank 140c and then utilized later. Also, when the water within the fluid circulation tube 130 is insufficient, e.g., for cooling or cleaning purposes, additional water may be supplied from the water tank 140c.

The solar cell support motion part 150 may be disposed adjacent the second lower portion 110c of the solar cell 110, e.g., the second lower portion 110c may be on the solar cell support motion part 150. The solar cell support motion part 150 may move vertically to adjust position and angle of the solar cell 110 when the photovoltaic power generation and cleaning processes are performed, as will be described in more detail below with reference to FIGS. 3B and 3C. The solar cell support motion part 150 may include a solar cell rack gear 150a disposed adjacent to the second lower portion 110c and a solar cell pinion gear 150b, so the solar cell support motion part 150 may move vertically by moving the solar cell pinion gear 150b, e.g., the solar cell rack gear 150a may be controlled in speed and direction of the vertical movement thereof by the solar cell pinion gear 150b coupled to a driving motor.

The cleaning part 160 may include a pump 160a, a valve 160b, and the nozzle 160c. The pump 160a may pump the water stored in the water tank 140c. The valve 160b may regulate an amount of the water passing through the pump 160a. The nozzle 160c may inject the water passing through the valve 160b onto a top surface 110d of the solar cell 110, i.e., a surface opposite the first and second lower portions 110b and 110c, in order to remove pollutants, e.g., fugitive dusts, lying on the top surface 110d of the solar cell 110. Thus, since the cleaning process is performed on the top surface 110d of the solar cell 110, the generation efficiency of the solar cell 110 may be highly maintained.

The cleaning part support motion part 170 may be disposed at a lower portion of the nozzle 160c, e.g., the cleaning part support motion part 170 may be between the nozzle 160c and the reference surface 10. The cleaning part support motion part 170 may vertically move the nozzle 160c when the photovoltaic power generation and cleaning processes are performed. In detail, the nozzle 160c may be moved vertically by a cleaning part rack gear 170a disposed at the lower portion of the nozzle 160c. The cleaning part rack gear 170a may be controlled in speed and direction of the vertical movement thereof by a cleaning part pinion gear 170b coupled to a driving motor. For example, during generation of the photovoltaic power, a top surface of the nozzle 160c, i.e., a surface facing away from the cleaning part support motion part 170, may be parallel to and substantially level with a top surface of the fluid circulation tube 130, i.e., a surface facing away from the cleaning part support motion part 170. When the cleaning process is performed, the cleaning part rack gear 170a of the cleaning part support motion part 170 may move the nozzle 160c upward, so the top surface of the nozzle 160c may be higher than the top surface of the fluid circulation tube 130, i.e., a distance between the top surface of the nozzle 160c and the reference surface 10 may be larger than a distance between the top surface of the fluid circulation tube 130 and the reference surface 10. As a result, during generation of the photovoltaic power, sunlight incident onto the solar cell 110 may not be shaded by the nozzle 160c, while during the cleaning process water injection onto the top surface 110d of the solar cell 110 may be improved.

The control part 180 may include a first controller 180a and a second controller 180b. The first controller 180a may control the vertical movement of the solar cell support motion part 150. In detail, the first controller 180a may control a forward/reversible rotation and a rotation speed of the driving motor coupled to the solar cell pinion gear 150b. The second controller 180b may control the vertical movement of the cleaning part support motion part 170. In detail, the second controller 180b may control a forward/reversible rotation and a rotation speed of the driving motor coupled to the cleaning part pinion gear 170b. In addition, the second controller 180b may control the pump 160a and the valve 160b.

The photovoltaic sensor 185 may detect the position of the sun with respect to the solar module 100 or the solar array 1000. When the sunlight is vertically irradiated onto the solar cell 110, solar photovoltaics have extremely high efficiency. However, a solar altitude is hourly changed. Thus, the photovoltaic sensor 185 may detect the position (e.g., altitude) of the sun to transmit the detected position information to the first controller 180a. The first controller 180a may control the solar cell support motion part 150 to change an angle of the solar cell 110 with respect to the reference surface 10, so that the sunlight may be incident on the top surface 110d of the solar cell 110 vertically, i.e., at about 90°.

The water discharge part 190 may include a water discharge funnel 190a, a water discharge tube 190b, and a water discharge tank 190c. The water discharge funnel 190a may be disposed below and spaced apart from the plurality of solar cells 110, i.e., the solar cell assembly 1110. The water discharge funnel 190a may collect the water used for cleaning the top surface of the solar call 110. The water discharge tube 190b may extend from the water discharge funnel 190a toward the water discharge tank 190c. The water discharge tank 190c may store the water used for cleaning the top surface of the solar cell 110 and passing through the water discharge tube 190b. The water stored in the water tank 190c may be recycled through foul water processing.

Hereinafter, operations of the solar module and the solar array according to an embodiment will be described with reference to FIGS. 3B and 3C. FIG. 3B illustrates a schematic view of the movement of the solar cell according to a position of the sun when the photovoltaic power is generated in the solar module according to an embodiment. FIG. 3C illustrates a schematic view of a cleaning process of the solar module according to an embodiment.

Referring to FIG. 3B, the solar module 100 according to an embodiment may be operated as follows during the photovoltaic power generation. The photovoltaic sensor 185 may detect the position (e.g., altitude) of the sun. Then, the detected signal may be transmitted to the first controller 180a of the control part 180. The first controller 180a may control the vertical movement of the solar cell support motion part 150 based on the transmitted signal. When the sunlight is vertically irradiated onto the solar cell 110, the solar photovoltaics have extremely high efficiency. Thus, the first controller 180a may control the solar cell support motion part 150 to change an angel of the solar cell 110 with respect to the reference surface 10, so that the sunlight may be vertically irradiated onto the solar cell 110. For example, when the sun is positioned approximately along a normal to the reference surface 10, the top surfaces 110d of the solar cells 110 may be adjusted to be substantially parallel to the reference surface 10 in order to ensure that sunlight irradiated onto the top surfaces 110d of the solar cells 110 is incident vertically onto the solar cells 110. In another example, when the sun is positioned at a non-right angle with respect to the reference surface 10, the top surfaces 110d of the solar cells 110 may be adjusted, e.g., the solar cell support motion part 150 may move the solar cell rack gear 150a upward to adjust one end of the solar cell 110, to be angled with respect to the reference surface 10 in order to ensure that sunlight S irradiated onto the top surfaces 110d of the solar cells 110 is incident vertically onto the solar cells 110.

Referring to FIG. 3C, the solar module 100 according to an embodiment may be operated as follows during the cleaning process. When a solar module is exposed to an external environment for a long time, pollutants, e.g., dust, may accumulate on the top surface thereof. As a result, an amount of incident sunlight reaching the solar cells may decrease, thereby reducing the photovoltaic power generation efficiency. Thus, in the solar module 100 according to an embodiment, the top surface 110d of the solar cell 110 may be cleaned for a predetermined time period or when the photovoltaic power generation efficiency is below a predetermined value. In the solar module 100 according to an embodiment, a cleaning fluid F, e.g., water, may be injected onto the top surface 110d of the solar cell 110 to perform the cleaning process.

In detail, water stored in the water tank 140c may be used for the cleaning process. The water may be injected onto the top surface 110d of the solar cell 110 through the pump 160a, the valve 160b, and the nozzle 160c under the control of the second controller 180b of the control part 180. During the cleaning process, the top surface of the nozzle 160c may be higher than the top surface of the fluid circulation tube 130 through the control of the second controller 180b. Specifically, the nozzle 160c may be moved upwardly by the cleaning part support motion part 170 under the control of the second controller 180b. When the cleaning process is performed, the second lower portion 110c of the solar cell 110 may be moved downwardly by the solar cell support motion part 150 under the control of the first controller 180a, i.e., all solar cells 110 may be inclined at angle with respect to the reference surface 10. The water used for cleaning the top surface 110d of the solar cell 110 may be discharged through the water discharge part 190 spaced apart from the lower portion of the solar cell 110. Specifically, water injected from the nozzles 160c onto the top surfaces 110d may flow along the inclined top surfaces 110d of the solar cells 110 toward the water discharge funnel 190a to remove any pollutants therefrom. The water used for cleaning the top surface 110d of the solar cell 110 may be collected into the water discharge funnel 190a, and then, the collected water may flow through the water discharge tube 190b to be stored in the water discharge tank 190c. The water stored in the water discharge tank 190c may be recycled through a foul water processing.

As above-described, the solar module and the solar array according to the embodiments may include a fluid circulation tube to prevent the solar cell from being heated by solar heat. In contrast, a conventional solar module may have increased temperature due to the collected sunlight, thereby having reduced electromotive force, which in turn, may deteriorate a power output of the solar module.

Also, the solar module and the solar array according to the embodiments may include a cleaning part at least partially within the fluid circulation tube, so fluid from the fluid circulation tube, e.g., water having an increased temperature due to cooling and removal of solar heat from the solar cells, may be used as warm water to remove pollutants from top surfaces of the solar cells. Therefore, the photovoltaic power generation efficiency of the solar module and solar array may be maximized. In contrast, a conventional solar module, which is exposed to an external environment, may have various pollutants, e.g., fugitive dusts, bird droppings, and sandy dusts, on tempered glasses of its solar cells, thereby having reduced optical transmittance.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A solar module, comprising:
a plurality of plate-shaped solar cells adjacent to each other, each solar cell having a polygonal cross-section from a plan view and at least one outer surface facing away from an interior of the solar module; and
a fluid circulation tube along the outer surfaces of the solar cells, the fluid circulation tube including cooling fluid.

2. The solar module as claimed in claim 1, wherein the plurality of solar cells is arranged in a square shape or a hexagonal shape.

3. The solar module as claimed in claim 1, wherein the fluid circulation tube contacts and overlaps an entire outer surface of each solar cell.

4. The solar module as claimed in claim 1, further comprising:
a solar cell support part at a first lower portion of a respective solar cell, the solar cell support part being configured to support the solar cell, and the first lower portion of the solar cell being at an edge of the solar cell adjacent to the fluid circulation tube; and
a solar cell support motion part at a second lower portion of the solar cell, the second lower portion being at an opposite edge of the solar cell with respect to the first lower portion, and the solar cell support motion part being configured to support and move the opposite edge of the solar cell.

5. The solar module as claimed in claim 4, further comprising:
a photovoltaic sensor configured to detect a position of the sun with respect to the solar module; and
a first controller configured to determine an angle of the solar cells with respect to the detected position of the sun, and to control movement of the solar cells via movement of the solar cell support motion part.

6. The solar module as claimed in claim 4, wherein the solar cell support motion part includes:
a solar cell rack gear disposed at the second lower portion of the solar cell;
a solar cell pinion gear disposed to correspond to the solar cell rack gear, the solar cell pinion gear being configured to vertically move the solar cell rack gear in order to move the opposite edge of the solar cell; and
a first controller configured to control the solar cell pinion gear.

7. The solar module as claimed in claim 1, further comprising a cleaning part at least partially within the fluid circulation tube, the cleaning part being configured to eject a portion of the cooling fluid from the fluid circulation tube onto top surfaces of the solar cells.

8. The solar module as claimed in claim 7, wherein the cleaning part includes:
a water tube connected to a water tank;
a pump configured to pump fluid from the water tank to the water tube;
a valve configured to regulate an amount of water passing through the pump;
a water support connected between the water tube and the fluid circulation tube, the water support being configured to support the fluid circulation tube;
a nozzle within the fluid circulation tube, the nozzle being configured to eject the cooling fluid from the fluid circulation tube onto the top surfaces of the solar cells; and
a second controller configured to control the pump and the valve.

9. The solar module as claimed in claim 8, wherein:
a top surface of the nozzle is substantially parallel to and level with a top surface of the fluid circulation tube during generation of photovoltaic power, and
the top surface of the nozzle is higher than the top surface of the fluid circulation tube during cleaning.

10. The solar module as claimed in claim 9, wherein the cleaning part further comprises:
a cleaning rack gear connected to the nozzle, the cleaning rack being configured to move the nozzle along a vertical direction; and
a cleaning pinion gear corresponding to the cleaning rack gear, the cleaning pinion gear being configured to vertically move the cleaning rack gear, and the second controller being configured to control the cleaning pinion gear.

11. The solar module as claimed in claim 7, further comprising a water discharge part configured to dispose the cooling fluid from the top surfaces of the solar cells, the water discharge part being positioned below and spaced from the solar cells.

12. The solar module as claimed in claim 11, wherein the water discharge part includes:
a water discharge funnel disposed below the plurality of solar cells, the water discharge funnel being configured to collect the cooling fluid from the top surfaces of the solar cells;
a water discharge tube extending from the water discharge funnel; and
a water discharge tank connected to the water discharge tube, the water discharge tank being configured to store the cooling fluid removed from the top surfaces of the solar cells.

13. A solar array, comprising:
a plurality of solar cell assemblies spaced apart from each other, each solar cell assembly having a polygonal shape and including a plurality of plate-shaped solar cells adjacent to each other, each solar cell having a polygonal cross-section from a plan view and at least one outer surface facing away from an interior of the solar cell assembly; and
a fluid circulation tube along the outer surfaces of the solar cells, the fluid circulation tube including cooling fluid.

14. The solar array as claimed in claim 13, wherein each of the solar cell assemblies has a square shape or a hexagonal shape.

15. The solar array as claimed in claim 13, further comprising:
a solar cell support part at a first lower portion of a respective solar cell, the solar cell support part being configured to support the solar cell, and the first lower portion of the solar cell being at an edge of the solar cell adjacent to the fluid circulation tube;
a solar cell support motion part at a second lower portion of the solar cell, the second lower portion being at an opposite edge of the solar cell with respect to the first lower portion, and the solar cell support motion part being configured to support and move the opposite edge of the solar cell; and
a first controller configured to control the solar cell support motion part.

16. The solar array as claimed in claim 15, further comprising a photovoltaic sensor configured to detect a position of the sun with respect to the solar array, the first controller being configured to determine angles of respective solar cells with respect to the detected position of the sun in order to control the solar cell support motion part.

17. The solar array as claimed in claim 13, further comprising a cleaning part at least partially within the fluid circulation tube, the cleaning part being configured to eject a portion of the cooling fluid from the fluid circulation tube onto top surfaces of the solar cells.

18. The solar array as claimed in claim 17, wherein the cleaning part comprises:
a water tube connected to a water tank;
a pump configured to pump fluid from the water tank to the water tube;
a valve configured to regulate an amount of water passing through the pump;
a water support connected between the water tube and the fluid circulation tube, the water support being configured to support the fluid circulation tube;
a nozzle within the fluid circulation tube, the nozzle being configured to eject the cooling fluid from the fluid circulation tube onto the top surfaces of the solar cells; and
a second controller configured to control the pump and the valve.

19. The solar array as claimed in claim 17, wherein the cleaning part includes:
a cleaning rack gear connected to the nozzle, the cleaning rack being configured to move the nozzle along a vertical direction; and
a cleaning pinion gear corresponding to the cleaning rack gear, the cleaning pinion gear being configured to vertically move the cleaning rack gear, and the second controller being configured to control the cleaning pinion gear.

20. The solar array as claimed in claim 13, further comprising a water discharge part configured to dispose the cooling fluid from the top surfaces of the solar cells, the water discharge part being positioned below and spaced from the solar cells.
